(19) United States
(12) Patent Application Publication
(10) Pub. No.: US 2009/0267082 A1
(43) Pub. Date: Oct. 29, 2009

(54) Semiconductor device and manufacturing method of the same

(75) Inventors: Takeo Yamamoto, Nishikamo-gun (JP); Takeshi Endo, Obu-city (JP); Eiichi Okuno, Mizuho-city (JP); Masaki Konishi, Toyota-city (JP); Hirokazu Fujiwara, Nishikamo-gun (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/385,594

(22) Filed: Apr. 14, 2009

(30) Foreign Application Priority Data
Apr. 24, 2008 (JP) 2008-114020

(51) Int. Cl. H01L 29/872; H01L 29/24; H01L 21/329

(52) U.S. Cl. 257/77; 257/472; 438/570; 257/E29.104; 257/E29.338; 257/E21.359

(57) ABSTRACT

A semiconductor device includes: a semiconductor element having a first surface and a second surface; a first electrode disposed on the first surface of the element; a second electrode disposed on the second surface of the element; and an insulation film covers a part of the first electrode, the first surface of the element and a part of a sidewall of the element. The above semiconductor device has small dimensions and a high breakdown voltage.

### CROSS REFERENCE TO RELATED APPLICATION

This application is based on Japanese Patent Application No. 2008-114020 filed on Apr. 24, 2008, the disclosure of which is incorporated herein by reference.

### FIELD OF THE INVENTION

The present invention relates to a semiconductor device and a manufacturing method of a semiconductor device.

### BACKGROUND OF THE INVENTION

A semiconductor device having high breakdown voltage is required. For example, it is required for the device that current does not flow between main electrodes even if a high voltage is applied to a diode in an inverse direction. Alternatively, it is required for the device that current does not flow between main electrodes even if a high voltage is applied between the main electrodes under a condition where a gate voltage is not applied to a gate electrode.

By improving a structure in the semiconductor device, the breakdown voltage of the device may be improved. Further, by using SiC material, the breakdown voltage may be improved. Here, the breakdown voltage of the device depends on not only a withstand voltage of the inside of the device but also occurrence degree of creeping discharge. The creeping discharge is such that discharge occurs along with a surface of the device. When the creeping discharge occurs, the breakdown voltage of the device is reduced.

JP-A-2003-197921 teaches a diode having high withstand voltage with reference to an inverse voltage. The diode includes an anode region having a P type conductivity, which is disposed on the surface of a drift layer having a N type conductivity. A termination region for reducing electric field concentration is formed at a periphery of the diode. The anode region is spaced apart from the termination region by a predetermined distance. Thus, a depletion layer expands toward the termination region when an inverse voltage is applied to the device. On the surface of the semiconductor device, a part of the anode electrode is covered with a surface protection film so that a distance between the anode electrode and the outer periphery of the termination region is sufficiently secured. Thus, the occurrence of the creeping discharge is restricted, so that the breakdown voltage of the device is improved.

It is required for the device to reduce the dimensions of the device. When the dimensions of the device are reduced, the distance between the electrode and the termination region in the device is shortened. In this case, for example, when a high voltage in an inverse direction is applied to the device in a breakdown test for the diode, the depletion layer may expand over the termination region. Thus, the electric potential gradient between the anode electrode as a ground potential side and the termination region as a high voltage side becomes large, so that the creeping discharge easily occurs. As a result, even when a voltage lower than the inside breakdown voltage of the device is applied to the device, the creeping discharge may occur at the outer periphery of the device. When the creeping discharge occurs, the total breakdown voltage of the device is reduced. In the diode shown in JP-A-2003-197921, by separating the anode electrode from the termination region by a predetermined distance, the creeping discharge is prevented. In the conventional art, it is difficult to reduce the dimensions of the device without reducing the breakdown voltage. Here, this difficult exists in a switching device such as a MOS transistor and a IGBT when a high voltage is applied to the switching device.

### SUMMARY OF THE INVENTION

In view of the above-described problem, it is an object of the present disclosure to provide a semiconductor device with small dimensions and high breakdown voltage. It is another object of the present disclosure to provide a manufacturing method of a semiconductor device.

According to a first aspect of the present disclosure, a semiconductor device includes: a semiconductor element having a first surface and a second surface; a first electrode disposed on the first surface of the element; a second electrode disposed on the second surface of the element; and an insulation film covers a part of the first electrode, the first surface of the element and a part of a sidewall of the element.

The dimensions of the above device are reduced together with improving a breakdown voltage.

According to a second aspect of the present disclosure, a method for manufacturing the semiconductor device according to the first aspect of the present disclosure, the method includes: forming the first electrode on the first surface of the semiconductor element; forming the second electrode on the second surface of the semiconductor element; forming a groove on the first surface of the element, wherein the groove does not penetrate the element; and filling the groove with the insulation material so that the insulation material covers the part of the sidewall of the element.

The above method provides the semiconductor device having small dimensions and a high breakdown voltage.

### BRIEF DESCRIPTION OF THE DRAWINGS

The above and other objects, features and advantages of the present invention will become more apparent from the following detailed description made with reference to the accompanying drawings. In the drawings:

FIG. 1 is a cross sectional view showing a diode according to a first embodiment;

FIG. 2 is a cross sectional view showing a manufacturing method of the diode in FIG. 1;

FIG. 3 is a cross sectional view showing the manufacturing method of the diode;

FIG. 4 is a cross sectional view showing a diode according to a second embodiment; and

FIG. 5 is a cross sectional view showing a manufacturing method of the diode in FIG. 4.

### DETAILED DESCRIPTION OF THE PREFERRED EMBODIMENTS

### First Embodiment

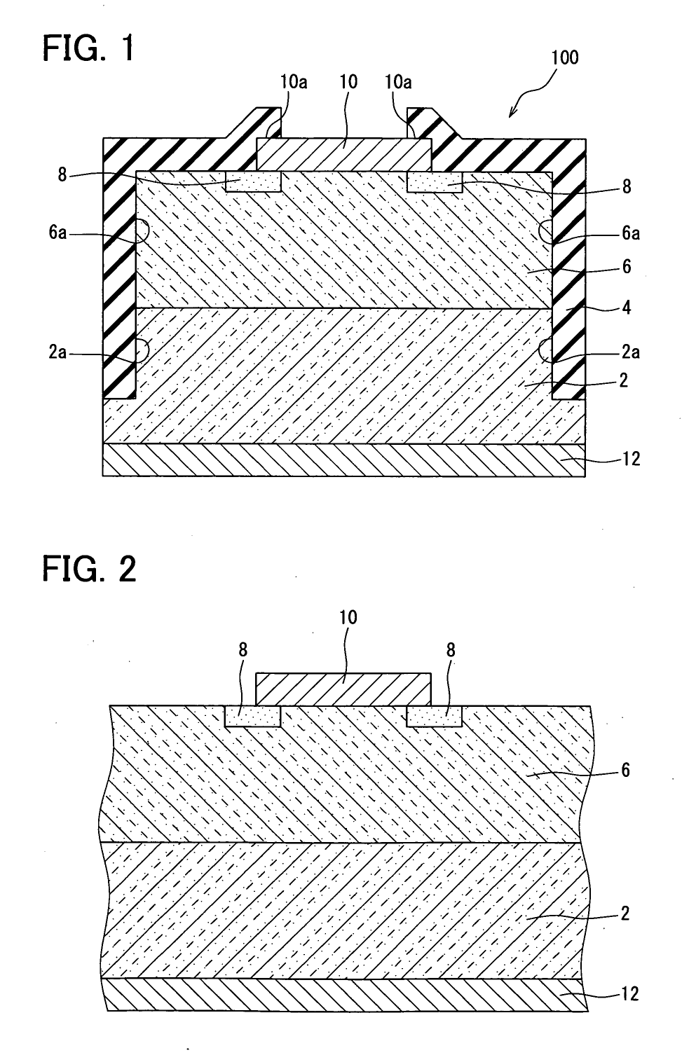

FIG. 1 shows a diode 100 as a semiconductor device according to a first embodiment. The diode 100 is a Schottky barrier diode. The diode 100 includes a N type SiC substrate 2. A drift layer 6 having a N conductive type is formed on a first principal surface of the substrate 2. A guard ring 8 having a P conductive type is formed in a termination region of the device 100. Specifically, the guard ring 8 is formed in a surface portion of the drift layer 6. On the first principal surface of the diode 100, the guard ring 8 surrounds a part of the drift layer 6. Specifically, the ring 8 surrounds an outline of an inside surface portion of the drift layer 6. By forming the guard ring 8 in the terminal region, a depletion layer expands toward the terminal region when an inverse voltage is applied to the diode 100. Thus, the breakdown voltage of the diode 100 is improved. An anode electrode 10 is formed on a part of the surface of the drift layer 6. The anode electrode 10 is disposed inside of the guard ring 8 so that the anode electrode 10 is surrounded with the guard ring 8. A part of the anode electrode 10 contacts the guard ring 8. A cathode electrode 12 is formed on a backside, i.e., the second principal surface of the substrate 2. In the diode 100, A SOG (spin on glass) film 4 as an insulation film is formed such that the SOG film 4 covers a periphery 10a of the anode electrode 10, a sidewall 6a of the drift layer 6 and a part of a sidewall 2a of the substrate 2. The SOG film 4 extends from the periphery 10a of the anode electrode 10 to the part of the sidewall 2a of the substrate 2 via the sidewall 6a of the drift layer 6.

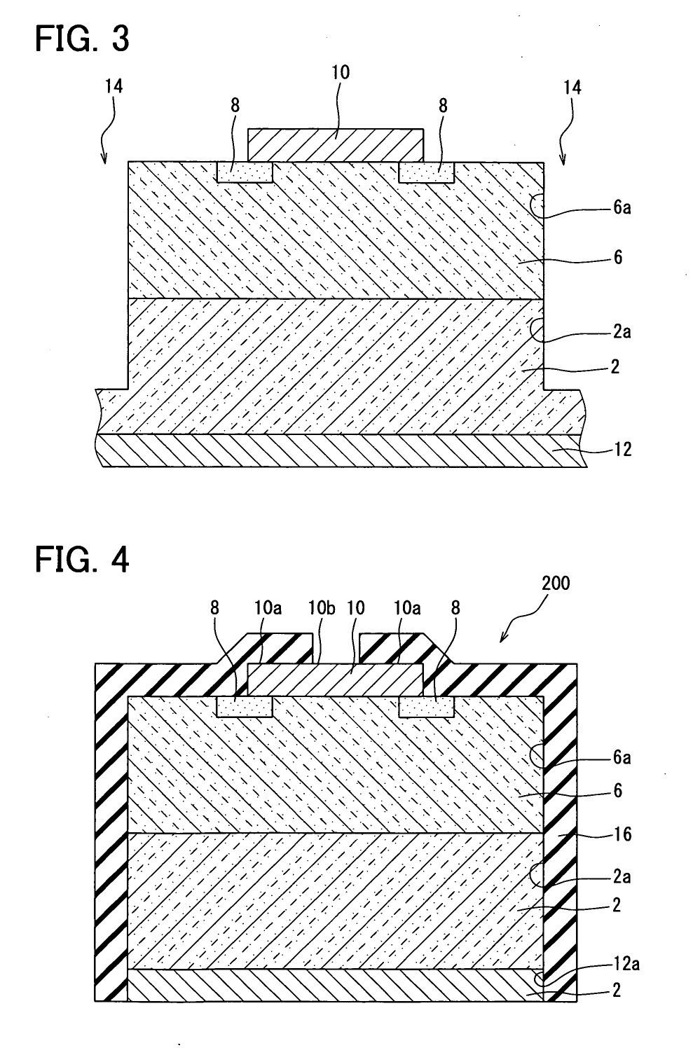

FIGS. 2 and 3 show a manufacturing method of the diode 100.

As shown in FIG. 2, the drift layer 6 is formed on the surface of the SiC substrate 2. The impurity concentration of the substrate 2 is 1×10¹⁹ cm⁻³, and the thickness of the substrate 2 is 350 μm. The impurity concentration of the drift layer 6 is 5×10¹⁵ cm⁻³, and the thickness of the drift layer 6 is 13 μm. Next, the guard ring 8 is formed in a part of the surface portion of the drift layer 6 in the termination region of the diode 6. Here, an aluminum ion is implanted in the part of the surface portion of the drift layer 6 so that the guard ring 8 is formed. After that, the substrate 2 is heated at 1600° C. so that an activation process is executed. The impurity concentration of the guard ring 8 is 1×10¹⁹ cm⁻³, and the thickness of the ring 8 is 0.8 μm. Next, an ohmic electrode is deposited on the backside of the substrate 2. The ohmic electrode is made of nickel. Then, the ohmic electrode is heated at 1000° C. so that a nickel film as the ohmic electrode becomes silicide film. The silicide ohmic electrode provides a part of the cathode electrode 12. Next, a Schottky electrode and an aluminum electrode are formed on the surface of the drift layer 6 by a vacuum vapor deposition method so that the anode electrode 10 is formed. The Schottky electrode is made of titanium or the like. Thus, a Ti film, a Ni film and an Al film for bonding to the ohmic electrode in this order are deposited on the backside of the silicide ohmic electrode so that the cathode electrode 12 is formed.

As shown in FIG. 3, a groove 14 is formed along with a dicing line as a dividing line by a half-dicing method such that the groove 14 does not penetrate the SiC substrate 2 and is disposed from the surface of the drift layer 6. The depth of the groove is 250 μm. A SOG liquid 4 is filled in the groove 14, and covered with a whole surface of the SiC substrate 2. The SOG liquid 4 is made of photosensitive material. Then, the SOG liquid 4 is heated so that the SOG liquid 4 is hardened. By performing a photo lithography method, a part of the SOG film 4 is removed so that a part of the anode electrode 10 other than the periphery 10a is exposed from the SOG film 4. Next, the SiC substrate 2 is cut from the backside of the substrate 2 along with the dicing line so that the SiC substrate 2 is divided into multiple diodes 100. Thus, the diode 100 is completed.

In the diode 100, the SOG film 4 is formed from the periphery 10a of the anode electrode 10, the sidewall 6a of the drift layer 6 to the part of the sidewall 2a of the substrate 2. Accordingly, when an inverse high voltage is applied to the diode 100, a distance between the periphery 10a of the anode electrode 10 and the sidewall 2a of the substrate is sufficiently secured. Here, the periphery 10a of the anode electrode 10 provides a ground potential, and the sidewall 2a of the substrate provides a high electric potential. Thus, the distance between a part of the SOG film 4 as the insulation film contacting the periphery 10a and another part of the SOG film 4 contacting the sidewall 2a is sufficient so that the creeping discharge is prevented. Even if the distance between the anode electrode 10 and the terminal region is not largely separated from each other, the creeping discharge is prevented by the sufficient length of the SOG film 4. Thus, the dimensions of the diode 100 are reduced, and the diode 100 has a sufficient high breakdown voltage. Further, since the diode 100 is made of SiC, the on-state resistance of a semiconductor device is reduced.

When the inverse high voltage is applied to the diode 100, the anode electrode 10 provides a ground electric potential. In this case, the creeping discharge may easily occur at the periphery 10a of the electrode 10. In the diode 100, since the periphery 10a of the anode electrode 10 is covered with the SOG film 4, the creeping discharge is prevented from occurring at the periphery 10a of the anode electrode 10. Further, the manufacturing cost of the diode 100 is reduced since the dimensions of the diode 100 are small. The diode 100 is made of SiC, so that the diode 100 is suitably used to apply a comparatively high voltage thereto. Even when a comparatively voltage, at which the creeping discharged occurs in the diode without the SOG film 4 as the insulation film, is applied to the diode 100 with the SOG film 4, the inside of the diode 100 functions normally. Thus, since SOG film 4 protects the diode 100 from generating the creeping discharge, the diode can function with the comparatively high voltage at which the creeping discharged occurs in the diode without the SOG film 4.

### Second Embodiment

FIG. 4 shows a diode 200 according to a second embodiment. The diode 200 is a Schottky barrier diode. The structure of the diode 200 other than a SOG film 16 is almost the same as the structure of the diode 100. In the diode 200, the SOG film 16 covers the anode electrode 10 other than a contact area 10b for connecting to an external circuit. In the diode 200, the SOG film 16 extends from a part of the anode electrode 10 to the sidewall 12a of the cathode electrode 12 via the sidewall 6a of the drift layer 6 and the sidewall 2a of the substrate 2.

A manufacturing method of the diode 200 will be explained. The drift layer 6 is formed on the surface of the SiC substrate 2. Then, the guard ring 8 is formed in a part of the surface portion of the drift layer 6 in the termination region of the diode 6. Next, the anode electrode 10 is formed on a part of the drift layer 6. The cathode electrode 12 is formed on the backside of the substrate 2. The groove 14 is formed along with a dicing line as a dividing line by a half-dicing method. A SOG liquid 16 is filled in the groove 14, and covered with a whole surface of the SiC substrate 2. Then, the SOG liquid 16 is heated so that the SOG liquid 16 is hardened. By performing a photo lithography method, a part of the SOG film 16 is removed so that only the contact area 10b of the anode electrode 10 is exposed from the SOG film 16. Specifically, the part of the SOG film 16 is selectively irradiated and developed so that the contact area 10b is exposed from the SOG film 16.

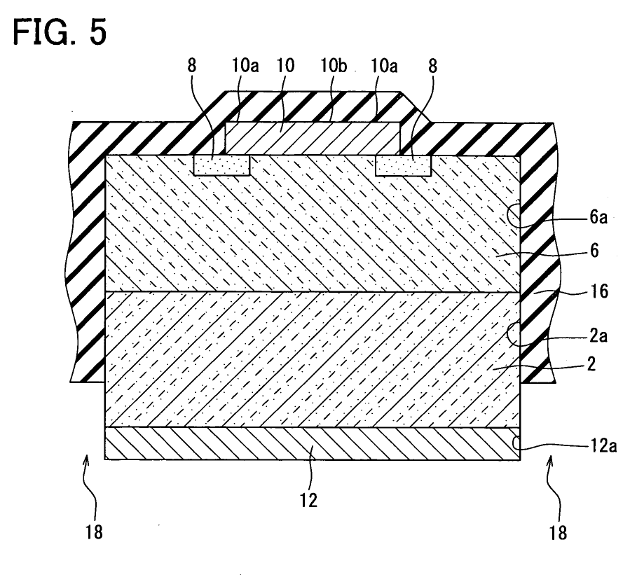

Then, as shown in FIG. 5, a second groove 18 is formed on the backside of the substrate 2 by a half dicing method such that the second groove 18 does not penetrate the substrate 2. The SOG liquid 16 is filled in the second groove 18. Then, the SOG liquid 16 in the second groove 18 is heated so that the SOG liquid 16 is hardened. By performing a photo lithography method, a part of the SOG film 16 on the backside of the substrate 2 is removed so that only the surface of the cathode electrode 12 is exposed from the SOG film 16. Specifically, the part of the SOG film 16 is selectively irradiated and developed so that the cathode electrode 12 is exposed from the SOG film 16. Next, the SiC substrate 2 is cut from the backside of the substrate 2 along with the dicing line so that the SiC substrate 2 is divided into multiple diodes 200. Thus, the diode 200 is completed.

In the diode 200, the SOG film 16 is formed from the anode electrode 10 to the sidewall 12a of the cathode electrode 12. Accordingly, when an inverse high voltage is applied to the diode 200, a distance between a part of the anode electrode 10 and the sidewall 12a of the cathode electrode 12 is sufficiently secured. Here, the part of the anode electrode 10 provides a ground potential, and the sidewall 12a of the cathode electrode 12 provides a high electric potential. Thus, the distance between a part of the SOG film 16 as the insulation film contacting the part of the anode electrode 10 and another part of the SOG film 16 contacting the sidewall 12a is sufficient so that the creeping discharge is prevented. Further, in the diode 200, the SOG film 16 extends toward the sidewall 12a of the cathode electrode 12, so that the creeping discharge is much prevented. Even if the distance between the anode electrode 10 and the terminal region is not largely separated from each other, the creeping discharge is prevented by the sufficient length of the SOG film 16. Thus, the dimensions of the diode 200 are reduced, and the diode 100 has a sufficient high breakdown voltage. Further, since the diode 200 is made of SiC, the on-state resistance of a semiconductor device is reduced.

(Modifications)

The guard ring 8 has the P conductive type, which is opposite to the n conductive type of the drift layer 6. By forming the guard ring 8 in the termination region, an electric field concentration near the guard ring 8 is reduced, so that the breakdown voltage of the diode 100, 200 is improved.

Preferably, the anode electrode 10 other than the contact area 10b for connecting to the external circuit is covered with an insulation film such as the SOG film 4, 16. In this case, the creeping discharge from the anode electrode 10 is effectively prevented.

Preferably, the surface of the cathode electrode 12 is not covered with the insulation film, i.e., the SOG film 4, 16. When the diode 100, 200 as a semiconductor device is mounted on a circuit board, the cathode electrode 12 may be bonded to the circuit board. The insulation film extends toward the sidewall 12a of the cathode electrode 12. If the insulation film does not extends on the surface of the cathode electrode 12, the diode 100, 200 is easily mounted on the circuit board.

Although the diode 100, 200 is the Schottky barrier diode, the diode 100, 200 may be a different type of diode. Alternatively, although the semiconductor device is the diode 100, 200, the device may be a MOS transistor, an IGBT or the like.

The above disclosure has the following aspects.

According to a first aspect of the present disclosure, a semiconductor device includes: a semiconductor element having a first surface and a second surface; a first electrode disposed on the first surface of the element; a second electrode disposed on the second surface of the element; and an insulation film covers a part of the first electrode, the first surface of the element and a part of a sidewall of the element.

In the above device, the second electrode may cover a whole of the second surface of the element or may be disposed on a part of the second surface of the element. The insulation film may cover a whole sidewall of the element.

In the above device, since the insulation film extends from the part of the first electrode, the first surface of the element and the part of the sidewall of the element, a distance between one end of the insulation film contacting the first electrode and the other end of the insulation film contacting the sidewall of the element is sufficiently secured when a high voltage is applied to the element. Thus, a creeping discharge is prevented by maintaining a sufficient length of the insulation film without increasing a distance between the first electrode and a termination region of the element. Thus, the dimensions of the device are reduced together with improving a breakdown voltage.

Alternatively, the insulation film may cover a whole of the sidewall of the element and a sidewall of the second electrode. In this case, a distance between one end of the insulation film contacting the first electrode and the other end of the insulation film contacting the sidewall of the second electrode is sufficiently secured when a high voltage is applied to the element. Further, since the insulation film extends to the sidewall of the second electrode, the creeping discharge is prevented.

Alternatively, the element may be made of silicon carbide. The SiC has electric filed intensity at insulation breakdown, which is ten times larger than that of Si. Accordingly, an on-state resistance of the device is reduced. When a comparatively high voltage is applied to the device, a creeping discharge may occur. However, in the above device, the insulation film prevents the creeping discharge from occurring. Here, when the device is made of Si, and a comparatively low voltage is applied to the device, a creeping discharge does not occur frequently.

Alternatively, the first electrode may cover a part of the first surface of the element, and the second electrode may cover a whole of the second surface of the element. The element includes a guard ring, which is disposed in a surface portion of the element and surrounds a part of the first surface of the element. An outer periphery of the first electrode contacts the guard ring so that the guard ring surrounds the first electrode, and the element provides one of a diode, a MOS transistor and an IGBT. Further, the element may provide a Schottky diode, and the element may further include a SiC substrate and a drift layer, which are stacked in this order. The drift layer is disposed on the first surface of the element, and the SiC substrate is disposed on the second surface of the element, and the SiC substrate has a first conductive type, the drift layer has the first conductive type, and the guard ring has a second conductive type. Furthermore, an impurity concentration of the drift layer may be smaller than that of the SiC substrate, and an impurity concentration of the guard ring may be larger than that of the drift layer. The first electrode provides an anode electrode, and the second electrode provides a cathode electrode. Further, the anode electrode may include a Schottky electrode and an aluminum electrode. The cathode electrode includes an ohmic electrode made of nickel silicide and a multi-layered electrode made of titanium, nickel and aluminum, and the insulation film is made of a SOG film. Furthermore, the insulation film may cover a whole of the sidewall of the element and a sidewall of the second electrode.

According to a second aspect of the present disclosure, a method for manufacturing the semiconductor device according to the first aspect of the present disclosure, the method includes: forming the first electrode on the first surface of the semiconductor element; forming the second electrode on the second surface of the semiconductor element; forming a groove on the first surface of the element, wherein the groove does not penetrate the element; and filling the groove with the insulation material so that the insulation material covers the part of the sidewall of the element.

The above method provides the semiconductor device having small dimensions and a high breakdown voltage.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A semiconductor device comprising:
a semiconductor element having a first surface and a second surface;
a first electrode disposed on the first surface of the element;
a second electrode disposed on the second surface of the element; and
an insulation film covers a part of the first electrode, the first surface of the element and a part of a sidewall of the element.

2. The semiconductor device according to claim 1,
wherein the insulation film covers a whole of the sidewall of the element and a sidewall of the second electrode.

3. The semiconductor device according to claim 1,
wherein the element is made of silicon carbide.

4. The semiconductor device according to claim 1,
wherein the first electrode covers a part of the first surface of the element,
wherein the second electrode covers a whole of the second surface of the element,
wherein the element includes a guard ring, which is disposed in a surface portion of the element and surrounds a part of the first surface of the element, wherein an outer periphery of the first electrode contacts the guard ring so that the guard ring surrounds the first electrode, and
wherein the element provides one of a diode, a MOS transistor and an IGBT.

5. The semiconductor device according to claim 4,
wherein the element provides a Schottky diode,
wherein the element further includes a SiC substrate and a drift layer, which are stacked in this order,
wherein the drift layer is disposed on the first surface of the element, and the SiC substrate is disposed on the second surface of the element, and
wherein the SiC substrate has a first conductive type, the drift layer has the first conductive type, and the guard ring has a second conductive type.

6. The semiconductor device according to claim 5,
wherein an impurity concentration of the drift layer is smaller than that of the SiC substrate,
wherein an impurity concentration of the guard ring is larger than that of the drift layer, and
wherein the first electrode provides an anode electrode, and the second electrode provides a cathode electrode.

7. The semiconductor device according to claim 6,
wherein the anode electrode includes a Schottky electrode and an aluminum electrode,
wherein the cathode electrode includes an ohmic electrode made of nickel silicide and a multi-layered electrode made of titanium, nickel and aluminum, and
wherein the insulation film is made of a SOG film.

8. The semiconductor device according to claim 7,
wherein the insulation film covers a whole of the sidewall of the element and a sidewall of the second electrode.

9. A method for manufacturing the semiconductor device according to claim 1, the method comprising:
forming the first electrode on the first surface of the semiconductor element;
forming the second electrode on the second surface of the semiconductor element;
forming a groove on the first surface of the element, wherein the groove does not penetrate the element; and
filling the groove with the insulation material so that the insulation material covers the part of the sidewall of the element.
